(19) United States
(12) Patent Application Publication
(10) Pub. No.: US 2025/0300612 A1
(43) Pub. Date: Sep. 25, 2025

(54) RECONFIGURABLE DUAL INPUT RECEIVER FRONT END

(71) Applicant: QUALCOMM Incorporated, San Diego, CA (US)

(72) Inventors: Zhijie XIONG, San Jose, CA (US); Alexander SO, San Jose, CA (US)

(21) Appl. No.: 18/610,917

(22) Filed: Mar. 20, 2024

(51) Int. Cl. H03F 3/24

(52) U.S. Cl. CPC H03F 3/245; H03F 2200/294; H03F 2200/451

(57) ABSTRACT

A low-noise amplifier (LNA) includes a first transistor, a second transistor, and a load coupled to a drain of the first transistor and a drain of the second transistor. The LNA also includes a first reactive impedance matching network including a first inductor and a second inductor inductively coupled with the first inductor, wherein the first inductor is coupled to a source of the first transistor, and the second inductor is coupled to a gate of the first transistor. The LNA also includes a second reactive impedance matching network including a third inductor and a fourth inductor inductively coupled with the third inductor, wherein the third inductor is coupled to a source of the second transistor, and the fourth inductor is coupled to a gate of the second transistor. The LNA also includes a switching circuit configured to enable or disable each of the reactive impedance matching networks.

### BACKGROUND

### Field

Aspects of the present disclosure relate generally to wireless communications, and, more particularly, to receivers.

### Background

A wireless device may include a low-noise amplifier (LNA) for amplifying radio frequency (RF) signals received by an antenna, and a power amplifier (PA) for amplifying RF signals to be transmitted from the antenna. The LNA and the PA may be integrated on a chip, the PA may be integrated on the chip with the LNA located outside of the chip, or the PA and the LNA may be integrated on the chip with an additional LNA located outside of the chip.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system including a low-noise amplifier (LNA). The LNA includes a first transistor, wherein a gate of the first transistor is coupled to a first input of the LNA, a second transistor, wherein a gate of the second transistor is coupled to a second input of the LNA, and a load coupled to a drain of the first transistor and a drain of the second transistor. The LNA also includes a first reactive impedance matching network comprising a first inductor and a second inductor inductively coupled with the first inductor, wherein the first inductor is coupled to a source of the first transistor, and the second inductor is coupled to the gate of the first transistor. The LNA also includes a second reactive impedance matching network comprising a third inductor and a fourth inductor inductively coupled with the third inductor, wherein the third inductor is coupled to a source of the second transistor, and the fourth inductor is coupled to the gate of the second transistor. The LNA also includes a switching circuit configured to enable or disable each of the first reactive impedance matching network and the second reactive impedance matching network.

A second aspect relates to a system including a low-noise amplifier (LNA). The LNA includes a first transistor, wherein a gate of the first transistor is coupled to a first input of the LNA, a first inductor, a first switch, wherein the first inductor and the first switch are coupled in series between a source of the first transistor and a ground, a second inductor inductively coupled with the first inductor, and a second switch, wherein the second inductor and the second switch are coupled in series between the gate of the first transistor and the ground. The LNA also includes a second transistor, wherein a gate of the second transistor is coupled to a second input of the LNA, a third inductor, a third switch, wherein the third inductor and the third switch are coupled in series between a source of the second transistor and the ground, a fourth inductor inductively coupled with the third inductor, and a fourth switch, wherein the fourth inductor and the fourth switch are coupled in series between the gate of the second transistor and the ground. The LNA also includes a load coupled to a drain of the first transistor and a drain of the second transistor.

### BRIEF DESCRIPTION OF THE DRAWINGS

FIG. 1 shows an example of a chip including a power amplifier and a low-noise amplifier according to certain aspects of the present disclosure.

FIG. 2 shows an exemplary implementation of a switch of FIG. 1 according to certain aspects of the present disclosure.

FIG. 3 shows an example of the chip of FIG. 1 in a first use case according to certain aspects of the present disclosure.

FIG. 4 shows an example of the chip of FIG. 1 in a second use case according to certain aspects of the present disclosure.

FIG. 5A shows an example of the chip of FIG. 1 in a third use case according to certain aspects of the present disclosure.

FIG. 5B shows another example of the chip of FIG. 1 in the third use case according to certain aspects of the present disclosure.

FIG. 6A shows an exemplary implementation of a low-noise amplifier including a shunt resistor for resistive impedance matching according to certain aspects of the present disclosure.

FIG. 6B shows the exemplary low-noise amplifier of FIG. 6A with exemplary signal routing to an input of the low-noise amplifier according to certain aspects of the present disclosure.

FIG. 7A shows an exemplary implementation of a low-noise amplifier including a first inductor, a second inductor, a third inductor, and a fourth inductor providing reactive impedance matching and a switching circuit according to certain aspects of the present disclosure.

FIG. 7B shows the low-noise amplifier of FIG. 7A with an alternative implementation of the switching circuit according to certain aspects of the present disclosure.

FIG. 8A shows a top view of an exemplary layout for the second inductor and the fourth inductor according to certain aspects of the present disclosure.

FIG. 8B shows a top view of an exemplary layout for the first inductor and the third inductor according to certain aspects of the present disclosure.

FIG. 9A shows a top view of another exemplary layout for the second inductor and the fourth inductor according to certain aspects of the present disclosure.

FIG. 9B shows a top view of another exemplary layout for the first inductor and the third inductor according to certain aspects of the present disclosure.

FIG. 10 shows an exemplary implementation of a load of a low-noise amplifier according to certain aspects of the present disclosure.

FIG. 11 shows an example of a low-noise amplifier including a switchable shunt inductor for programming a source degeneration inductance according to certain aspects of the present disclosure.

FIG. 12 shows an exemplary layout of the shunt inductor of FIG. 11 according to certain aspects of the present disclosure.

FIG. 13 shows an example of a low-noise amplifier including a shunt switch coupled to a tap of a source degeneration inductor for programming a source degeneration inductance according to certain aspects of the present disclosure.

FIG. 14 shows diagram of an example of an environment including a wireless device that includes a transceiver according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

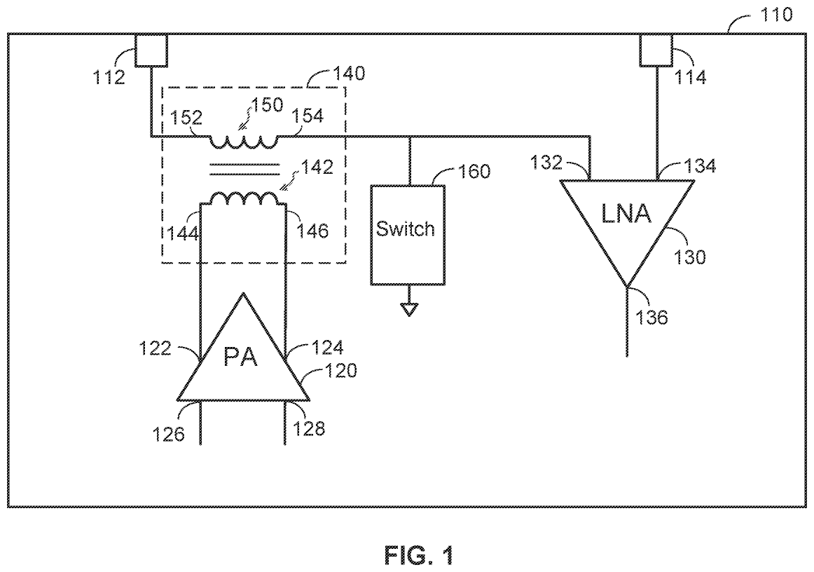

FIG. 1 shows an example of a chip 110 including a power amplifier (PA) 120 and a low-noise amplifier (LNA) 130. As discussed further below, the chip 110 supports different use cases, eliminating the need for separate chip designs to support the different use cases.

In this example, the chip 110 also includes a first pad 112, a second pad 114, a transformer 140, and a switch 160. The pads 112 and 114 are used for coupling the chip 110 to one or more external components, as discussed further below. A pad may also be referred to as a contact pad, a port, or another term.

In this example, the PA 120 has a first input 126, a second input 128, a first output 122, and a second output 124. In a transmit mode, the PA 120 is configured to receive a differential RF signal at the first and second inputs 126 and 128, amplify the differential RF signal, and output the amplified differential RF signal at the first and second outputs 122 and 124. It is to be appreciated that the PA 120 may be singled ended in some implementations. The PA 120 may receive the differential RF signal from a mixer (not shown) configured to frequency upconvert a baseband signal or an intermediate frequency (IF) signal into the differential RF signal. The mixer may be integrated on the chip 110.

The LNA 130 has a first input 132, a second input 134, and an output 136. In a receive mode, the LNA 130 receives an RF signal at the first input 132 or the second input 134 depending on the use case, as discussed further below. The LNA 130 is configured to amplify the received RF signal, and output the amplified RF signal at the output 136. The output 136 may be coupled to a mixer (not shown) configured to frequency downconvert the amplified RF signal into a baseband signal or an IF signal. The mixer may be integrated on the chip 110. In some implementations, another amplifier (e.g., a transconductance amplifier or another type of amplifier) may be coupled between the output 136 and the mixer. In the example in FIG. 1, the second input 134 of the LNA 130 is coupled to the second pad 114.

The transformer 140 includes a first inductor 142 and a second inductor 150 inductively (i.e., magnetically) coupled with the first inductor 142. The first inductor 142 is coupled between the first output 122 and the second output 124 of the PA 120. More particularly, the first inductor 142 has a first terminal 144 coupled to the first output 122 of the PA 120 and a second terminal 146 coupled to the second output 124 of the PA 120. The first inductor 142 may include a center tap (not shown) coupled to a supply voltage or another voltage.

The second inductor 150 has a first terminal 152 and a second terminal 154. The first terminal 152 is coupled to the first pad 112, and the second terminal 154 is coupled to the switch 160. In certain aspects, the switch 160 couples the second terminal 154 of the second inductor 150 to ground (or some reference potential) in the transmit mode. Thus, in the transmit mode, the second inductor 150 is coupled between the first pad 112 and ground. The first input 132 of the LNA 130 may be coupled to the second terminal 154 of the second inductor 150.

In the transmit mode, the transformer 140 receives the amplified differential RF signal from the first and second outputs 122 and 124 of the PA 120 at the first inductor 142, and converts the amplified differential RF signal into a single-ended RF signal at the second inductor 150. The single-ended RF signal is then transmitted from an antenna (not shown in FIG. 1) coupled to the first pad 112.

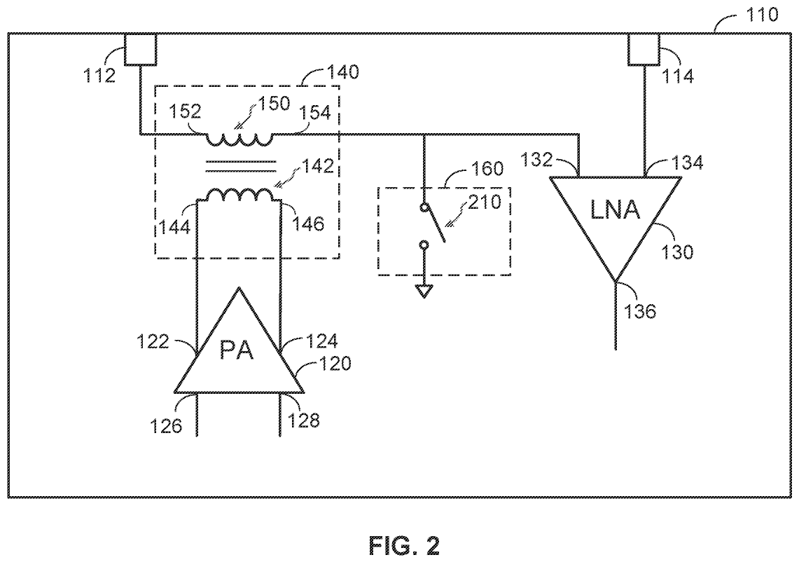

FIG. 2 shows an example where the switch 160 is implemented with a shunt switch 210 coupled between the second terminal 154 of the second inductor 150 and ground (or some reference potential). In the transmit mode, the switch 210 is closed (i.e., turned on) to couple the second terminal 154 of the second inductor 150 to ground.

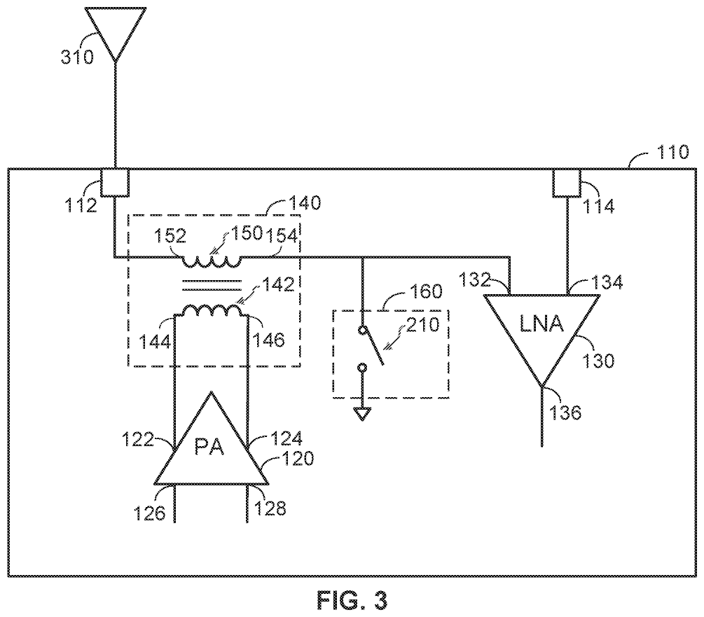

As discussed above, the chip 110 supports different use cases. In this regard, three exemplary use cases supported by the chip 110 are discussed below with reference to FIGS. 3, 4, 5A, and 5B.

FIG. 3 shows an example of a first use case in which both transmit RF signals and receive RF signal pass through the first pad 112. The first use case may be used to reduce costs at the expense of lower receive performance, as discussed further below.

In this example, the first pad 112 is coupled to an antenna 310. For example, the chip 110 and the antenna 310 may be mounted on a substrate (e.g., a printed circuit board). In this example, the first pad 112 and the antenna 310 may be coupled via one or more metal traces on and/or embedded in the substrate. However, it is to be appreciated that the present disclosure is not limited to this example. In this example, the antenna 310 is used to transmit RF signal from the PA 120 in the transmit mode and receive RF signals for the LNA 130 in the receive mode.

In the transmit mode, the switch 160 couples the second terminal 154 of the second inductor 150 to ground. The transformer 140 receives the amplified differential RF signal from the PA 120 at the first inductor 142, and converts the amplified differential RF signal into the single-ended RF signal at the second inductor 150. The single-ended RF signal is then output to the antenna 310 via the first pad 112.

In the receive mode, the switch 160 decouples the second terminal 154 of the second inductor 150 from ground, and the PA 120 is turned off. For the example where the switch 160 is implemented with the shunt switch 210, the shunt switch 210 is open (i.e., turned off) in the receive mode. In the receive mode, the LNA 130 is configured to receive an RF signal at the first input 132 from the antenna 310 via the first pad 112. The LNA 130 amplifies the received RF signal, and outputs the amplified RF signal at the output 136 (e.g., outputs the amplified RF signal to a mixer or another amplifier). Note that the second input 134 of the LNA 130 and the second pad 114 are not used in the first use case.

In the receive mode, the RF signal passes through the second inductor 150 of the transformer 140 to the first input 132 of the LNA 130. As a result, the second inductor 150 causes signal loss in the RF signal and degrades the noise figure (NF) of the receive path. Also, the LNA 130 may have a lower performance (e.g., lower NF) compared with an external LNA, as discussed further below. However, the first use case lowers costs by not using an external LNA, which adds costs. Thus, the first use case may be used to reduce costs at the expense of lower receive performance.

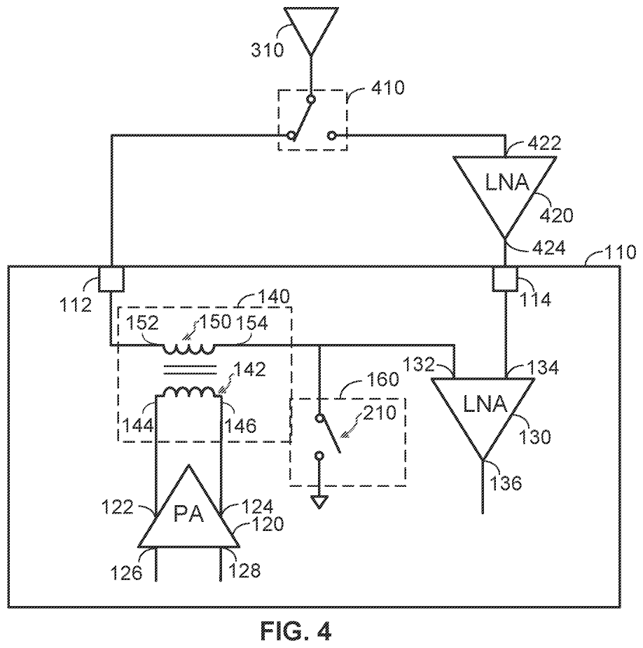

FIG. 4 shows an example of a second use case in which an external switch 410 and an external LNA 420 are used. The external switch 410 and the external LNA 420 increase costs compared with the first use case. However, the external switch 410 and the external LNA 420 improve receive performance compared with the first use case, as discussed further below.

In the example shown in FIG. 4, the external LNA 420 has an input 422 and an output 424 coupled to the second pad 114. In certain aspects, the external LNA 420 provides better noise performance and/or gain than the LNA 130 on the chip 110. For example, the external LNA 420 may be fabricated using a process technology (e.g., a gallium arsenide (GaAs) process technology) that provides the external LNA 420 with better performance (e.g., lower NF which improves sensitivity) than the LNA 130.

The external switch 410 is coupled between the antenna 310 and the first pad 112. The external switch 410 is also coupled between the antenna 310 and the input 422 of the external LNA. In this example, the external switch 410 is configured to switch between the transmit mode and the receive mode by coupling the antenna 310 to the first pad 112 in the transmit mode and coupling the antenna 310 to the input 422 of the external LNA 420 in the receive mode. The external switch 410 may also be referred to as an RF switch, an antenna switch, a transmit/receive (T/R) switch, or another term.

In the transmit mode, the external switch 410 couples the antenna 310 to the first pad 112, and the switch 160 couples the second terminal 154 of the second inductor 150 to ground. The transformer 140 receives the amplified differential RF signal from the PA 120 at the first inductor 142, and converts the amplified differential RF signal into the single-ended RF signal at the second inductor 150. The single-ended RF signal is then output to the antenna 310 via the first pad 112 and the external switch 410.

In the receive mode, the external switch 410 couples the antenna 310 to the input 422 of the external LNA 420, and the PA 120 is turned off. The external LNA 420 is configured to receive an RF signal at the input 422 from the antenna 310 via the external switch 410, amplify the received RF signal, and output the amplified RF signal at the output 424. The amplified RF signal from the external LNA 420 is then input to the second input 134 of the LNA 130 on the chip 110 via the second pad 114. The LNA 130 may provide additional amplification of the RF signal and output the amplified RF at the output 136 (e.g., output the amplified RF signal to a mixer or another amplifier). Note that the first input 132 of the LNA 130 and the first pad 112 are not used in the receive mode in the second use case. Since the first input 132 of the LNA 130 is not used in the second use case, the switch 160 may be on or off in the receive mode.

In the receive mode, the external LNA 420 provides better receive performance (e.g., lower NF for increased sensitivity) compared with the first use case. Receive performance may further be improved since the receive RF signal does not pass through the second inductor 150 of the transformer 140 in the second use case, and therefore does not undergo the signal loss and NF degradation caused by the second inductor 150. However, the addition of the external switch 410 and the external LNA 420 in the second use case increase costs compared with the first use case.

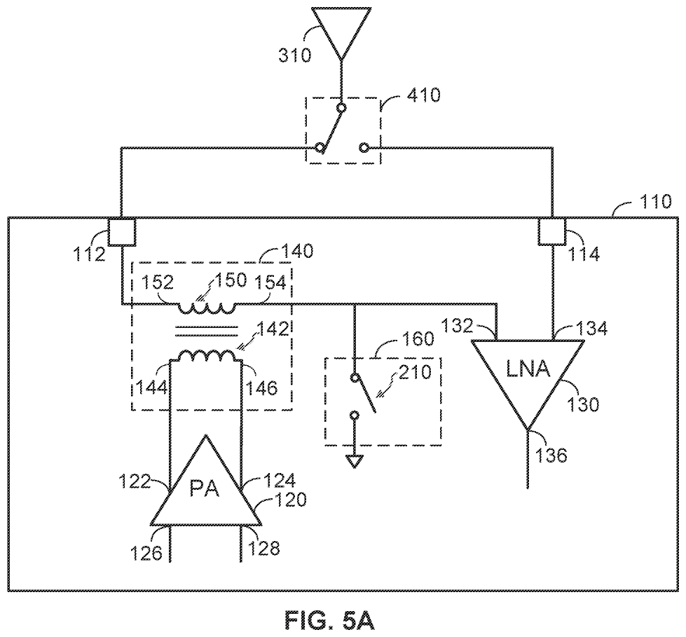

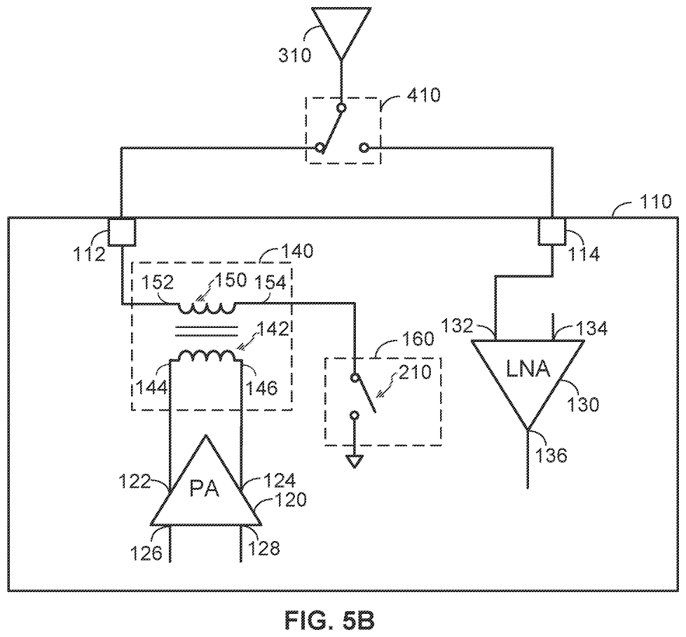

FIG. 5A shows an example of a third use case in which the external switch 410 is used to switch between the transmit mode and the receive mode. The external LNA 420 is not used in the third use case.

In the example shown in FIG. 5A, the external switch 410 is coupled between the antenna 310 and the first pad 112. The external switch 410 is also coupled between the antenna 310 and the second pad 114. In this example, the external switch 410 is configured to switch between the transmit mode and the receive mode by coupling the antenna 310 to the first pad 112 in the transmit mode and coupling the antenna 310 to the second pad 114 in the receive mode.

In the transmit mode, the external switch 410 couples the antenna 310 to the first pad 112, and the switch 160 couples the second terminal 154 of the second inductor 150 to ground. The transformer 140 receives the amplified differential RF signal from the PA 120 at the first inductor 142, and converts the amplified differential RF signal into the single-ended RF signal at the second inductor 150. The single-ended RF signal is then output to the antenna 310 via the first pad 112 and the external switch 410.

In the receive mode, the external switch 410 couples the antenna 310 to the second pad 114, and the PA 120 is turned off. The LNA 130 receives an RF signal at the second input 134 from the antenna 310 via the external switch 410 and the second pad 114. The LNA 130 amplifies the received RF signal, and outputs the amplified RF signal at the output 136 (e.g., outputs the amplified RF signal to a mixer or another amplifier). Note that, in the example shown in FIG. 5A, the first input 132 of the LNA 130 and the first pad 112 are not used in the receive mode in the third use case. Since the first input 132 of the LNA 130 is not used in this example, the switch 160 may be on or off in the receive mode.

In the third use case, the receive RF signal does not pass through the second inductor 150 of the transformer 140, and therefore does not undergo the signal loss and NF degradation caused by the second inductor 150 in the first use case.

FIG. 5B shows an example of an alternative configuration for the third use case. In this example, the signal routing (e.g., metal routing) between the second inductor 150 and the first input 132 of the LNA 130 is broken, and the signal routing (e.g., metal routing) between the second pad 114 and the second input 134 of the LNA 130 is broken. In this example, the second pad 114 is coupled to the first input 132 of the LNA 130 (i.e., the RF signal received from the antenna 310 through the external switch 410 is rerouted to the first input 132 of the LNA 130). A drawback of the configuration shown in FIG. 5B is that this configuration may require changing the metal routing on the chip 110.

In the transmit mode, the external switch 410 couples the antenna 310 to the first pad 112, and the switch 160 couples the second terminal 154 of the second inductor 150 to ground. The transformer 140 receives the amplified differential RF signal from the PA 120 at the first inductor 142, and converts the amplified differential RF signal into the single-ended RF signal at the second inductor 150. The single-ended RF signal is then output to the antenna 310 via the first pad 112 and the external switch 410.

In the receive mode, the external switch 410 couples the antenna 310 to the second pad 114, and the PA 120 is turned off. The LNA 130 receives an RF signal at the first input 132 from the antenna 310 via the external switch 410 and the second pad 114. The LNA 130 amplifies the received RF signal, and outputs the amplified RF signal at the output 136 (e.g., outputs the amplified RF signal to a mixer or another amplifier). Since the first input 132 of the LNA 130 is decoupled from the second inductor 150 of the transformer 140 in this example, the switch 160 may be on or off in the receive mode. Alternatively, the routing between the second terminal 154 of the second inductor 150 and the switch 160 may be broken, and the second terminal 154 of the second inductor 150 may be coupled to ground (or some reference potential).

Although the first input 132 of the LNA 130 is coupled to the external switch 410 through the second pad 114 in the example shown in FIG. 5B, it is to be appreciated that, in other implementations, the first input 132 of the LNA 130 may be coupled to the external switch 410 through another pad (not shown) on the chip 110.

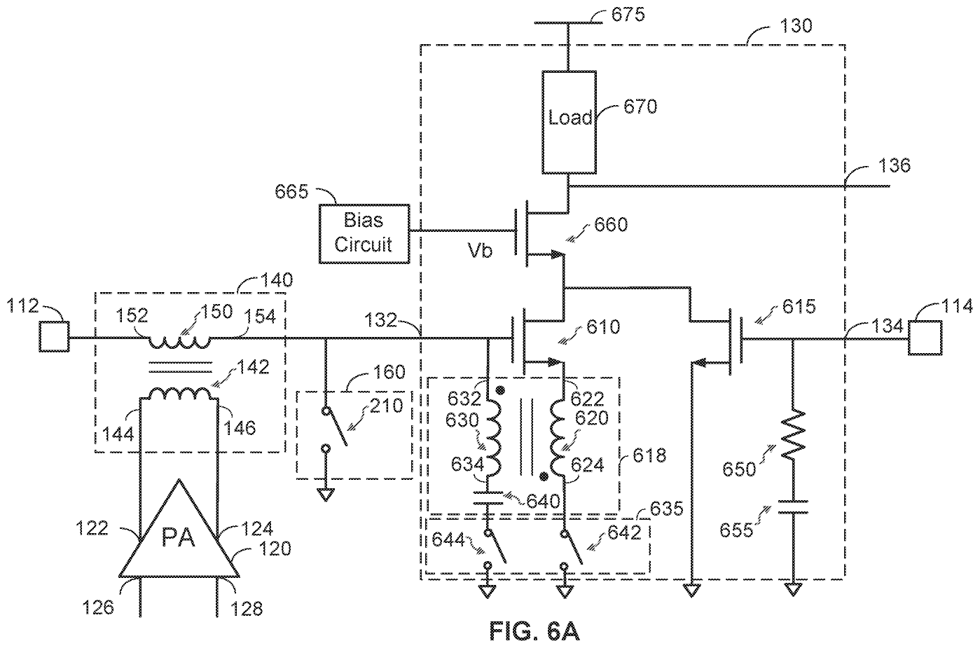

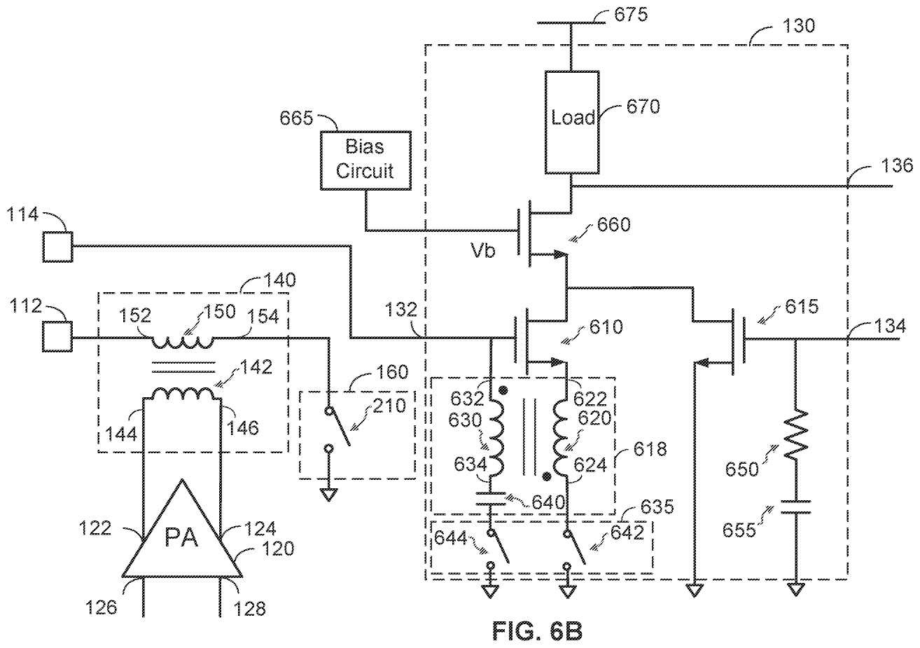

FIGS. 6A and 6B show an exemplary implementation of the LNA 130 supporting multiple use cases including the exemplary use cases discussed above. FIG. 6A shows an example in which the second input 134 of the LNA 130 is coupled to the second pad 114, and FIG. 6B shows an example in which the first input 132 of the LNA 130 is coupled to the second pad 114 with the first input 132 of the LNA 130 decoupled from the second inductor 150 of the transformer 140.

In this example, the LNA 130 includes a first transistor 610, a second transistor 615, a third transistor 660, and a load 670. As discussed further below, the first transistor 610 receives the RF signal at the first input 132 and drives the load 670 based on the RF signal in the first use case and the third use case. The second transistor 615 receives the RF signal at the second input 134 and drives the load 670 based on the RF signal in the second use case.

The gate of the first transistor 610 is coupled to the first input 132 of the LNA 130. In this example, the LNA 130 further includes a reactive impedance matching network 618 and a switching circuit 635. In the example shown in FIGS. 6A and 6B, the reactive impedance matching network 618 includes a first inductor 620, a second inductor 630, and a capacitor 640, in which the first inductor 620 is coupled to the source of the first transistor 610, the second inductor 630 is coupled to the gate of the first transistor 610, and the second inductor 630 is inductively coupled with the first inductor 620. The inductive coupling between the first inductor 620 and the second inductor 630 provides the reactive impedance matching network 618 with reactive impedance matching with inductive feedback. The reactive impedance matching network 618 may provide input impedance and noise impedance matching, and achieve a low NF over a wide frequency band. As used herein, a reactive impedance matching network is an impedance matching network including reactive components (e.g., inductors). The inductances of the inductors 620 and 630 may be chosen to provide impedance matching at the first pad 112 (e.g., 50 Ohm or another impedance). Since the second inductor 150 of the transformer 140 is coupled between the first pad 112 and the first input 132 of the LNA 130 in the example shown in FIG. 6A, the second inductor 150 may be taken into account in choosing the inductances of the inductors 620 and 630 for impedance matching in this example.

In the example in FIGS. 6A and 6B, the switching circuit 635 includes a first switch 642 and a second switch 644. The first inductor 620 and the first switch 642 are coupled in series between the source of the first transistor 610 and ground (or some reference potential). The first inductor 620 provides the first transistor 610 with source degeneration when the first switch 642 is closed. The second inductor 630, the capacitor 640, and the second switch 644 are coupled in series between the gate of the first transistor 610 and ground (or some reference potential). In the example shown in FIG. 6, the first inductor 620 has a first terminal 622 coupled to the source of the first transistor 610 and a second terminal 624 coupled to the first switch 642, and the second inductor 630 has a first terminal 632 coupled to the gate of the first transistor 610 and a second terminal 634 coupled to the capacitor 640. In this example, the second inductor 630 is coupled to the second switch 644 through the capacitor 640. However, it is to be appreciated that the present disclosure is not limited to this example.

In this example, the switching circuit 635 disables the reactive impedance matching network 618 when the switches 642 and 644 are open (i.e., turned off). In this case, the switching circuit 635 provides very high impedances (i.e., off impedances of the switches 642 and 644) at the inductors 620 and 630, which prevent current flow through the inductors 620 and 630. The switching circuit 635 enables the reactive impedance matching network 618 when the switches 642 and 644 are closed (i.e. turned on).

The gate of the second transistor 615 is coupled to the second input 134 of the LNA 130, and the source of the second transistor 615 is coupled to ground (or some reference potential). In this example, the LNA 130 further includes a shunt resistor 650 and a capacitor 655 coupled in series between the gate of the second transistor 615 and ground (or some reference potential). The shunt resistor 650 provides resistive impedance matching at the second pad 114 (e.g., 50 Ohm or another impedance). The shunt resistor 650 occupies a small area on the chip 110, and therefore is able provide impedance matching with a small area penalty. However, the shunt resistor 650 suffers from wideband thermal noise, which degrades noise performance, as discussed further below.

The source of the third transistor 660 is coupled to the drain of the first transistor 610 and the drain of the second transistor 615, and the gate of the third transistor 660 is coupled to a bias circuit 665 configured to bias the gate of the third transistor 660 with a bias voltage Vb. In this example, the third transistor 660 is configured as a common-gate amplifier that provides approximately unity current gain and a high impedance at the drain of the third transistor 660. An LNA with a common-gate amplifier may be referred to as a cascode LNA.

The load 670 is coupled between a supply rail 675 providing a supply voltage and the drain of the third transistor 660. The load 670 may include an inductor, a capacitor, a transformer, or any combination thereof. An exemplary implementation of the load 670 is discussed below. The output 136 of the LNA 130 may be coupled between the load 670 and the third transistor 660, or coupled to an internal node of the load 670. In some implementations, the output 136 may be a differential output including a first output and a second output coupled to the load 670, as discussed further below. In some implementations, the third transistor 660 may be omitted with the load 670 coupled between the supply rail 675 and the drains of the first and second transistors 610 and 615 without the third transistor 660.

Exemplary operations of the LNA 130 in the different use cases will now be discussed according to certain aspects.

The transmit mode may be the similar for the first use case, the second use case, and the third use case. In the transmit mode, the switch 160 couples the second terminal 154 of the second inductor 150 to ground (e.g., the shunt switch 210 is closed), and the switches 642 and 644 are open. The transformer 140 receives the amplified differential RF signal from the PA 120 at the first inductor 142, and converts the amplified differential RF signal into the single-ended RF signal at the second inductor 150. The single-ended RF signal is then output to the antenna 310 via the first pad 112 in the first use case and via the first pad 112 and the external switch 410 in the second and third use cases.

In the receive mode in the first use case, the exemplary configuration illustrated in FIG. 6A is used. In this example, in the receive mode, the switch 160 decouples the second terminal 154 of the second inductor 150 from ground (e.g., the shunt switch 210 is open), and the switches 642 and 644 are closed (which enables the reactive impedance matching network 618). The gate of the first transistor 610 receives an RF signal from the antenna 310 via the first pad 112, and generates a current based on the received RF signal. The current drives the load 670 to generate an amplified RF signal at the output 136. In the first use case, the first inductor 620 and the second inductor 630 provide reactive impedance matching, as discussed above. Note that the second transistor 615 and the second pad 114 are not used in the first use case.

In the receive mode in the second use case, the exemplary configuration illustrated in FIG. 6A is used. In this example, in the receive mode, the switch 160 couples the second terminal 154 of the second inductor 150 to ground, and the switches 642 and 644 are open (which disables the reactive impedance matching network 618) since the first transistor 610 is not used in the second use case. The gate of the second transistor 615 receives the amplified RF signal from the external LNA 420 via the second pad 114, and generates a current based on the received RF signal. The current drives the load 670 to generate an amplified RF signal at the output 136. Note that the first transistor 610 and the first pad 112 are not used in the receive mode in the second use case.

In the second use case, the shunt resistor 650 provides resistive impedance matching at the second pad 114 (e.g., 50 Ohms). As discussed above, the shunt resistor 650 degrades the NF of the RF signal. In this case, the noise degradation by the shunt resistor 650 diminishes some of the improvement in noise performance provided by the external LNA 420. Thus, while the shunt resistor 650 takes up a small area on the chip 110, the resistive impedance matching of the shunt resistor 650 degrades on chip noise performance in the second use case.

In the receive mode in the third use case, the exemplary configuration shown in FIG. 6B may be used. In this example, the first input 132 of the LNA 130 is decoupled from the second inductor 150 of the transformer 140 and coupled to the external switch 410 through the second pad 114 (shown in FIG. 6B) or another pad (not shown). In this example, in the receive mode, the switches 642 and 644 are closed (which enables the reactive impedance matching network 618). The gate of the first transistor 610 receives an RF signal from the antenna 310 through the external switch 410, and generates a current based on the received RF signal. The current drives the load 670 to generate an amplified RF signal at the output 136. Note that the second transistor 615 is not used in the receive mode in the third use case in this example.

In this example, the first input 132 of the LNA 130 is used to amplify the RF signal from the antenna 310 in the third use case. This is because the noise performance at the second input 134 (which is degraded by the shunt resistor 650) may be too low to achieve a desired level of performance without assistance from the external LNA 420 used in second use case. To overcome this, the first input 132 of the LNA 130 (which has higher noise performance than the second input 134 in this example) is used in the third use case. However, using the first input 132 of the LNA 130 in the third use case may require changing the metal routing on the chip 110 to reroute the first input 132 to the second pad 114 or another pad (not shown), which may increase cost and development time.

To address the above, aspects of the present disclosure replace the shunt resistor 650 in FIG. 6 with a reactive impedance matching network that improves on chip NF compared with the shunt resistor 650. In certain aspects, the reactive impedance matching network includes inductors that may be stacked with the inductors 620 and 630 on the chip 110. This allows the inductors of the reactive impedance matching network to be integrated on the chip 110 with high area efficiency. The above features and other features of the present disclosure are discussed further below.

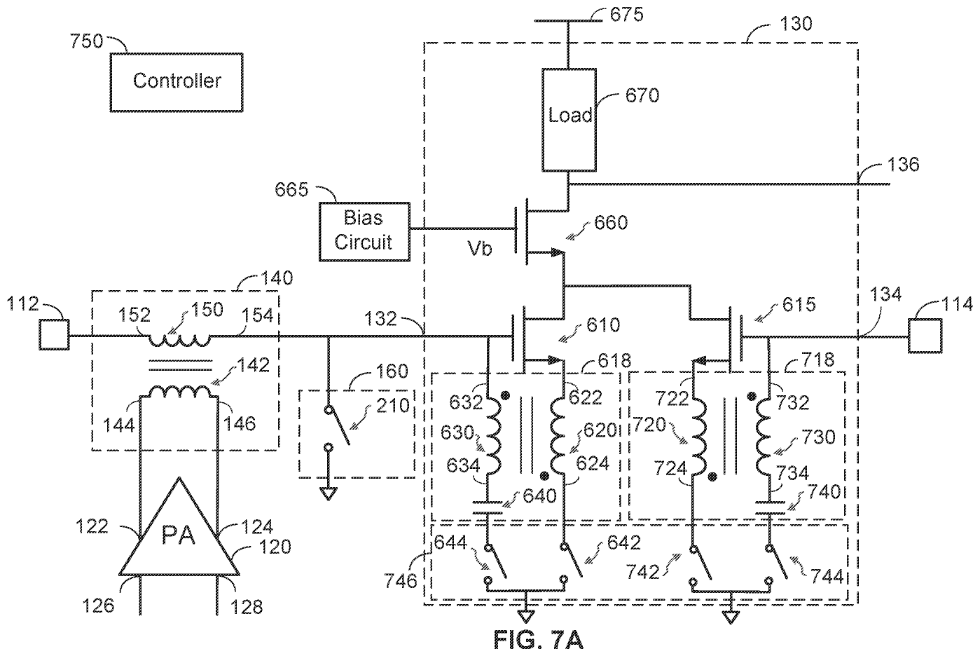

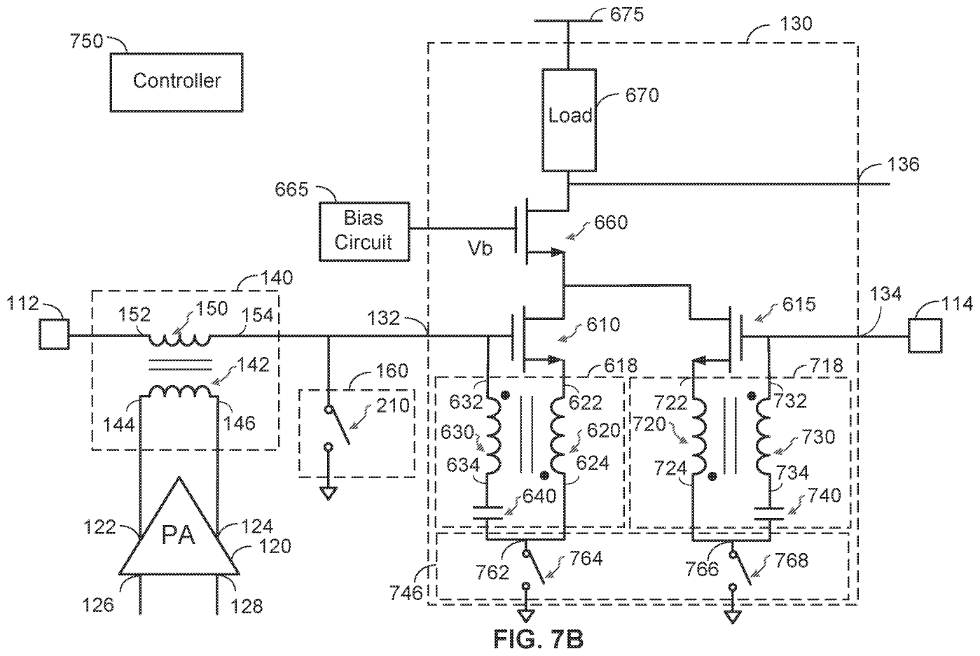

FIG. 7A shows an exemplary implementation of the LNA 130 in which the resistive impedance matching of FIGS. 6A and 6B is replaced with a second reactive impedance matching network 718 for improved noise performance. In the example shown in FIG. 7A, the second reactive impedance matching network 718 includes a third inductor 720, a fourth inductor 730, and a capacitor 740, in which the third inductor 720 is coupled to the source of the second transistor 615, the fourth inductor 730 is coupled to the gate of the second transistor 615, and the fourth inductor 730 is inductively coupled with the third inductor 720. In the discussion below, the reactive impedance matching network 618 is referred to as the first reactive impedance matching network 618.

The inductive coupling between the third inductor 720 and the fourth inductor 730 provides the second reactive impedance matching network 718 with reactive impedance matching with inductive feedback. The second reactive impedance matching network 718 may provide input impedance and noise impedance matching, and achieve a low NF over a wide frequency band. The inductances of the inductors 720 and 730 may be chosen to provide impedance matching at the second pad 114 (e.g., 50 Ohm or another impedance). The second reactive impedance matching network 718 may provide at least a 3 dB improvement in the on chip NF compared with the shunt resistor 650.

In this example, the LNA 130 also includes a switching circuit 746 configured to enable or disable each of the first reactive impedance matching network 618 and the second reactive impedance matching network 718, as discussed further below. In the example in FIG. 7A, the switching circuit 746 includes the first switch 642 and the second switch 644 discussed above. The switching circuit 746 also includes a third switch 742 and a fourth switch 744. The third inductor 720 and the third switch 742 are coupled in series between the source of the second transistor 615 and ground (or some reference potential). The third inductor 720 provides the second transistor 615 with source degeneration when the third switch 742 is closed. The fourth inductor 730, the capacitor 740, and the fourth switch 744 are coupled in series between the gate of the second transistor 615 and ground (or some reference potential). In the example shown in FIG. 7A, the third inductor 720 has a first terminal 722 coupled to the source of the second transistor 615 and a second terminal 724 coupled to the third switch 742, and the fourth inductor 730 has a first terminal 732 coupled to the gate of the second transistor 615 and a second terminal 734 coupled to the capacitor 740. In this example, the fourth inductor 730 is coupled to the fourth switch 744 through the capacitor 740. However, it is to be appreciated that the present disclosure is not limited to this example. Each of the switches 642, 644, 742, and 744 may be implemented with a transistor, a transmission gate, or another type of switch.

In this example, the switching circuit 746 disables the first reactive impedance matching network 618 when the switches 642 and 644 are open (i.e., turned off), and enables the first reactive impedance matching network 618 when the switches 642 and 644 are closed (i.e., turned on), as discussed above. In this example, the switching circuit 746 disables the second reactive impedance matching network 718 when the switches 742 and 744 are open (i.e., turned off). In this case, the switching circuit 746 provides very high impedances (i.e., off impedances of the switches 742 and 744) at the inductors 720 and 730, which prevent current flow through the inductors 720 and 730. The switching circuit 746 enables the second reactive impedance matching network 718 when the switches 742 and 744 are closed (i.e. turned on).

Exemplary operations of the LNA 130 in the different use cases will now be discussed according to certain aspects. In this example, a controller 750 controls switching of the switching circuit 746. The controller 750 may also control the on/off states of the switch 160. For the example where the switching circuit 746 includes the switches 642, 644, 742, and 744, the controller 750 controls the on/off states of the switches 642, 644, 742, and 744. For ease of illustration, the individual connections between the controller 750 and the switches 160, 642, 644, 742, and 744 are not shown in FIG. 7.

The transmit mode may be the similar for the first use case, the second use case, and the third use case. In the transmit mode, the controller 750 causes the switch 160 to couple the second terminal 154 of the second inductor 150 to ground (e.g., closes the shunt switch 210). The controller 750 may also cause the switching circuit 746 to disable the reactive impedance matching networks 618 and 718 (e.g., open the switches 642, 644, 742, and 744). The transformer 140 receives the amplified differential RF signal from the PA 120 at the first inductor 142, and converts the amplified differential RF signal into the single-ended RF signal at the second inductor 150. The single-ended RF signal is then output to the antenna 310 via the first pad 112 in the first use case and via the first pad 112 and the external switch 410 in the second and third use cases.

In the receive mode in the first use case, the controller 750 causes the switch 160 to decouple the second terminal 154 of the second inductor 150 from ground (e.g., opens the shunt switch 210). The controller 750 also causes the switching circuit 746 to enable the first reactive impedance matching network 618 and disable the second reactive impedance matching network 718 (e.g., closes the first and second switches 642 and 644 and opens the third and fourth switches 742 and 744). The gate of the first transistor 610 receives an RF signal from the antenna 310 via the first pad 112 (shown in FIG. 3), and generates a current based on the received RF signal. The current drives the load 670 to generate an amplified RF signal at the output 136. In the first use case, the first inductor 620 and the second inductor 630 provide reactive impedance matching, as discussed above. Note that the second transistor 615 and the second pad 114 are not used in the first use case.

In the receive mode in the second use case, the controller 750 may cause the switch 160 to couple the second terminal 154 of the second inductor 150 to ground since the first transistor 610 is not used in the second use case. The controller 750 also causes the switching circuit 746 to enable the second reactive impedance matching network 718 and disable the first reactive impedance matching network 618 (e.g., opens the first and second switches 642 and 644 and closes the third and fourth switches 742 and 744). The gate of the second transistor 615 receives the amplified RF signal from the external LNA 420 via the second pad 114 (shown in FIG. 4), and generates a current based on the received RF signal. The current drives the load 670 to generate an amplified RF signal at the output 136. Note that the first transistor 610 and the first pad 112 are not used in the receive mode in the second use case.

In the second use case, the third inductor 720 and the fourth inductor 730 provide reactive impedance matching at the second pad 114 (e.g., 50 Ohms), which may improve on chip noise performance by at least 3 dB compared with the shunt resistor 650 in FIGS. 6A and 6B.

In the receive mode in the third use case, the controller 750 may cause the switch 160 to couple the second terminal 154 of the second inductor 150 to ground. The controller 750 also causes the switching circuit 746 to enable the second reactive impedance matching network 718 and disable the first reactive impedance matching network 618 (e.g., opens the first and second switches 642 and 644 and closes the third and fourth switches 742 and 744). The gate of the second transistor 615 receives an RF signal from the antenna 310 via the second pad 114 and the external switch 410 (shown in FIG. 5A), and generates a current based on the received RF signal. The current drives the load 670 to generate an amplified RF signal at the output 136. Note that the first transistor 610 and the first pad 112 are not used in the receive mode in the third use case.

In the third use case, the third inductor 720 and the fourth inductor 730 provide reactive impedance matching at the second pad 114 (e.g., 50 Ohms), which improves noise performance by at least 3 dB compared with the shunt resistor 650 in FIGS. 6A and 6B. The improved noise performance increases the sensitivity of the LNA 130 in the third use case, allowing the LNA 130 to sense weaker RF signals from the antenna 310. Because of the improved noise performance at the second input 134 provided by the reactive impedance matching, the second input 134 of the LNA 130 may be used to amplify the RF signal in the third use case. This avoids the need of changing the metal routing on the chip 110 to reroute the second pad 114 or another pad (not shown) to the first input 132 of the LNA 130.

It is to be appreciated that the switching circuit 746 is not limited to the exemplary implementation shown in FIG. 7A, and that the switching circuit 746 may be implemented with other arrangements of switches configured to enable or disable each of the reactive impedance matching networks 618 and 718. In this regard, FIG. 7B shows another exemplary implementation of the switching circuit 746 according to certain aspects.

In this example, the first inductor 620 is coupled between the source of the first transistor 610 and a node 762, and the second inductor 630 and the capacitor 640 are coupled in series between the gate of the first transistor 610 and the node 762. Also, the third inductor 720 is coupled between the source of the second transistor 615 and a node 766, and the fourth inductor 730 and the capacitor 740 are coupled in series between the gate of the second transistor 615 and the node 766. In this example, the switching circuit 746 includes a first switch 764 and a second switch 768. The first switch 764 is between the node 762 and ground (or some reference potential), and the second switch 768 is between the node 766 and ground (or some reference potential).

In this example, the controller 750 causes the switching circuit 746 to enable the first reactive impedance matching network 618 and disable the second reactive impedance matching network 718 by closing the first switch 764 and opening the second switch 768. The controller 750 causes the switching circuit 746 to disable the first reactive impedance matching network 618 and enable the second reactive impedance matching network 718 by opening the first switch 764 and closing the second switch 768.

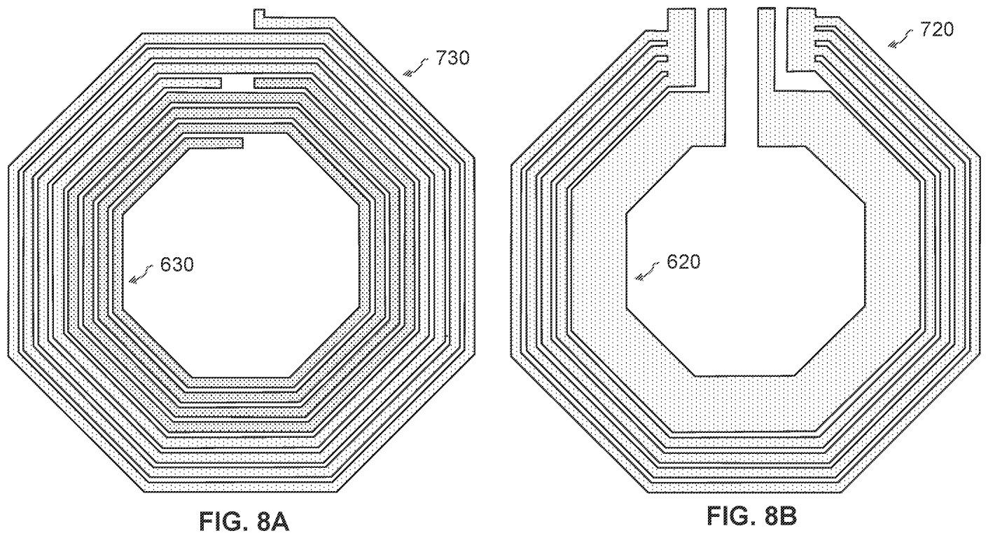

FIG. 8A shows a top view of an exemplary layout of the second inductor 630 and the fourth inductor 730, and FIG. 8B shows a top view of an exemplary layout of the first inductor 620 and the third inductor 720. As discussed further below, the exemplary layout allows the inductors 720 and 730 in the reactive impedance matching network of the second transistor 615 (i.e., the second reactive impedance matching network 718) to be integrated with the inductors 620 and 630 in the reactive impedance matching network of the first transistor 610 (i.e., the first reactive impedance matching network 618) with high area efficiency.

FIG. 8A shows an example in which each of the second inductor 630 and the fourth inductor 730 is implemented with a planar inductor formed using a first metal layer (e.g., using lithographic and etching processes). In other words, the second inductor 630 and the fourth inductor 730 are in the first metal layer in this example.

In this example, the second inductor 630 is located within the fourth inductor 730 to conserve area. However, it is to be appreciated that the fourth inductor 730 may be located within the second inductor 630 in other implementations. In the example shown in FIG. 8A, the second inductor 630 is located within an area enclosed by the fourth inductor 730. This significantly reduces the chip area taken up by the second inductor 630 and the fourth inductor 730 compared with, for example, locating the inductors 630 and 730 side by side on the chip 110.

In the example shown in FIG. 8A, each of the second inductor 630 and the fourth inductor 730 includes a spiral inductor. However, it is to be appreciated that the second inductor 630 and the fourth inductor 730 are not limited to this example. It is also to be appreciated that the second inductor 630 and the fourth inductor 730 may be formed in different metal layers in some implementations and still maintain the same or similar chip footprint as above (e.g., by staking the second inductor 630 and the fourth inductor 730).

FIG. 8B shows an example in which each of the first inductor 620 and the third inductor 720 is implemented with a planar inductor formed using a second metal layer (e.g., using lithographic and etching processes). In other words, the first inductor 620 and the third inductor 720 are in the second metal layer in this example. The second metal layer may be above or below the first metal layer with a dielectric material disposed between the second metal layer and first metal layer.

In this example, the first inductor 620 is located within the third inductor 720 to conserve area. However, it is to be appreciated that the third inductor 720 may be located within the first inductor 620 in other implementations.

In the example shown in FIG. 8B, the first inductor 620 includes a loop inductor and the third inductor 720 includes multiple loop inductors (e.g., three loop inductors) coupled in parallel. In this example, the first inductor 620 is located within the inner loop of the third inductor 720 to conserve area. It is to be appreciated that the first inductor 620 and the third inductor 720 are not limited to the example shown in FIG. 8B. For example, in other implementations, the first inductor 620 may include two or more loop inductors coupled in parallel, and the third inductor 720 may include one loop inductor. In general, each of the first inductor 620 and the third inductor 720 may include one or more loop inductors.

The first inductor 620 and the third inductor 720 may be stacked on top of the second inductor 630 and the fourth inductor 730 or below the second inductor 630 and fourth inductor 730 to facilitate inductive coupling between the first inductor 620 and the second inductor 630 and inductive coupling between the third inductor 720 and the fourth inductor 730.

It is to be appreciated that the first inductor 620 and the third inductor 720 may be formed in different metal layers in some implementations and still maintain the same or similar chip footprint as above (e.g., by staking the first inductor 620 and the third inductor 720). In some implementations, each of the inductors 620, 630, 720, and 730 may be formed in different metal layers, in which the inductors 620, 630, 720, and 730 are stacked to achieve high area efficiency.

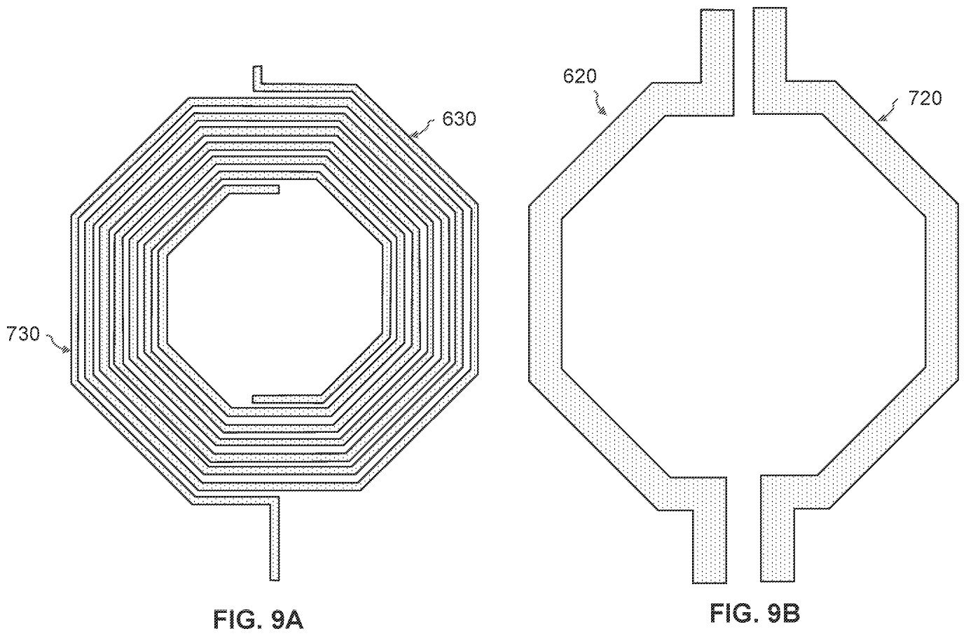

FIG. 9A shows a top view of another exemplary layout of the second inductor 630 and the fourth inductor 730, and FIG. 9B shows a top view of another exemplary layout of the first inductor 620 and the third inductor 720.

FIG. 9A shows an example in which each of the second inductor 630 and the fourth inductor 730 is implemented with a planar inductor formed using the first metal layer (e.g., using lithographic and etching processes). In other words, the second inductor 630 and the fourth inductor 730 are in the first metal layer in this example. In the example shown in FIG. 9A, the second inductor 630 includes a first spiral inductor and the fourth inductor 730 includes a second spiral inductor interleaved with the first spiral inductor.

FIG. 9B shows an example in which each of the first inductor 620 and the third inductor 720 is implemented with a planar inductor formed using the second metal layer (e.g., using lithographic and etching processes). In other words, the first inductor 620 and the third inductor 720 are in the second metal layer in this example. The second metal layer may be above or below the first metal layer with a dielectric material disposed between the second metal layer and first metal layer. In the example shown in FIG. 9B, each of the first inductor 620 and the third inductor 720 is implemented with a half loop inductor.

The first inductor 620 and the third inductor 720 may be stacked on top of the second inductor 630 and the fourth inductor 730 or below the second inductor 630 and fourth inductor 730 to facilitate inductive coupling between the first inductor 620 and the second inductor 630 and inductive coupling between the third inductor 720 and the fourth inductor 730.

It is to be appreciated that the inductors 620, 630, 720, and 730 are not limited to the exemplary layouts illustrated in FIGS. 8A, 8B, 9A, and 9B.

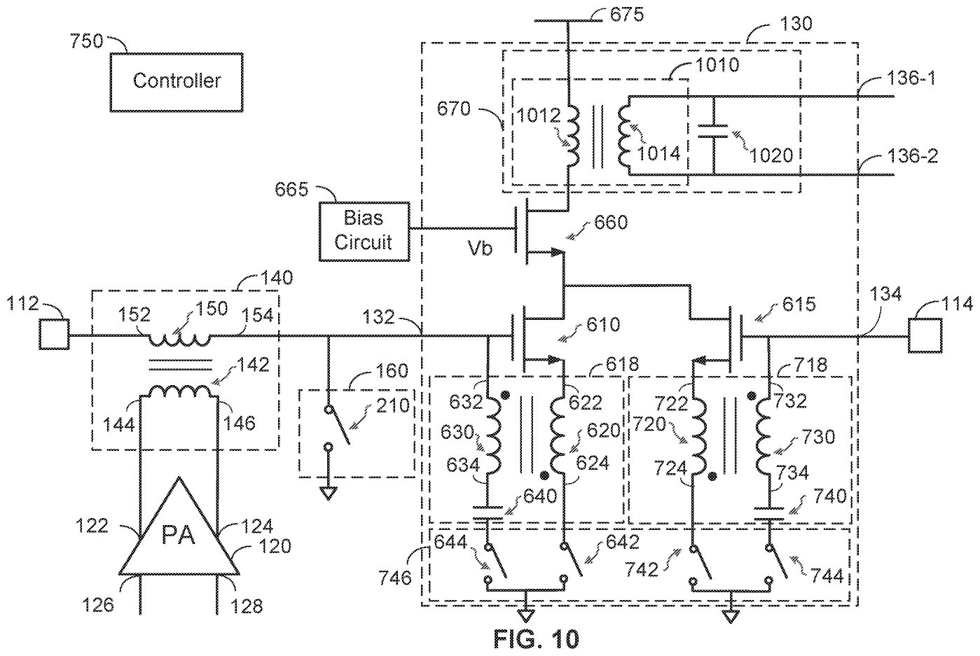

FIG. 10 shows an exemplary implementation of the load 670 according to certain aspects. In this example, the load 670 includes a transformer 1010 and a capacitor 1020. The transformer 1010 includes a first inductor 1012 and a second inductor 1014. The first inductor 1012 is coupled between the supply rail 675 and the drain of the third transistor 660, and the capacitor 1020 is coupled in parallel with the second inductor 1014. In this example, the output 136 of the LNA 130 is a differential output including a first output 136-1 and a second output 136-2 in which the second inductor 1014 is coupled between the first output 136-1 and the second output 136-2.

It is to be appreciated that the load 670 is not limited to the exemplary implementation shown in FIG. 10. For example, in other implementations, the load 670 may include an inductor and a capacitor coupled in parallel between the supply rail 675 and the drain of the third transistor 660.

In certain aspects, the source degeneration inductance of the second transistor 615 may be programmable to increase or decrease the source degeneration inductance. For example, the source degeneration inductance may be increased to increase linearity or the source degeneration inductance may be decreased to increase noise performance and gain.

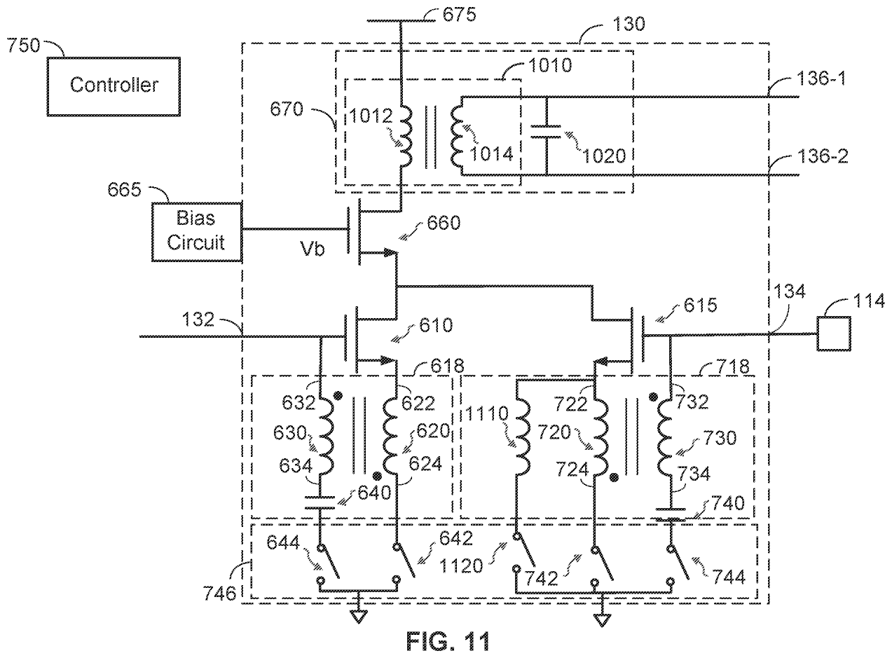

FIG. 11 shows an example for implementing programmable source degeneration inductance in the LNA 130 according to certain aspects. In this example, the LNA 130 includes a fifth inductor 1110 between the source of the second transistor 615 and the switching circuit 746. In the example shown in FIG. 11, the switching circuit 746 includes a fifth switch 1120 in which the fifth inductor 1110 and the fifth switch 1120 are coupled in series between the source of the second transistor 615 and ground (or some reference potential). The one/off state of the fifth switch 1120 may be controlled by the controller 750.

In this example, the controller 750 may program the source degeneration inductance of the second transistor 615 by controlling the fifth switch 1120 and the third switch 742. For example, the controller 750 may program the source degeneration inductance to a first inductance value by coupling the third inductor 720 to ground and decoupling the fifth inductor 1110 from ground (e.g., closing the third switch 742 and opening the fifth switch 1120). In this case, the first inductance value is approximately equal to the inductance of the third inductor 720. The controller 750 may program the source degeneration inductance to a second inductance value by coupling the third inductor 720 and the fifth inductor 1110 to ground (e.g., closing both the third switch 742 and the fifth switch 1120). In this case, the fifth inductor 1110 is coupled in parallel with the third inductor 720, which lowers the source degeneration inductance (i.e., the second inductance value is lower than the first inductance value).

Thus, in this example, the first inductance value is higher than the second inductance value, and therefore provides higher linearity compared with the second inductance value. The second inductance value (i.e., the parallel combination of the fifth inductor 1110 and the third inductor 720) is lower than the first inductance value, and therefore provides higher noise performance (e.g., lower NF) and higher gain than the first inductance value. Thus, in this example, the controller 750 may program the source degeneration inductance of the second transistor 615 to the first inductance value (i.e., close the third switch 742 and open the fifth switch 1120) for higher linearity. The controller 750 may program the source degeneration inductance of the second transistor 615 to the second inductance value (i.e., close both the third switch 742 and the fifth switch 1120) for higher noise performance and higher gain (which improve sensitivity).

For example, the controller 750 may program the source degeneration inductance to the first inductance value for higher linearity when the signal strength of the receive RF signal at the second input 134 is high. In this example, the higher linearity reduces distortion in the receive RF signal caused by the LNA 130. For example, the signal strength of the receive RF signal at the second input 134 may be high when the antenna 310 is located close to the transmitter transmitting the RF signal (e.g., a hotspot, a base station transmitter, or the like). The signal strength of the receive RF signal at the second input 134 may also be high in the second use case where the external LNA 420 amplifies the RF signal to a high signal strength before the LNA 130.

The controller 750 may program the source degeneration inductance to the second inductance value for higher noise performance and higher gain when the signal strength of the receive RF signal at the second input 134 is low. In this example, the higher noise performance and higher gain increases the sensitivity of the LNA 130. For example, the signal strength of the receive RF signal at the second input 134 may be low when the antenna 310 is located far away the transmitter transmitting the RF signal (e.g., a hotspot, a base station transmitter, or the like). The signal strength of the receive RF signal at the second input 134 may also be low in the third use case where the RF signal from the antenna 310 is not amplified by an external LNA before going to the LNA 130.

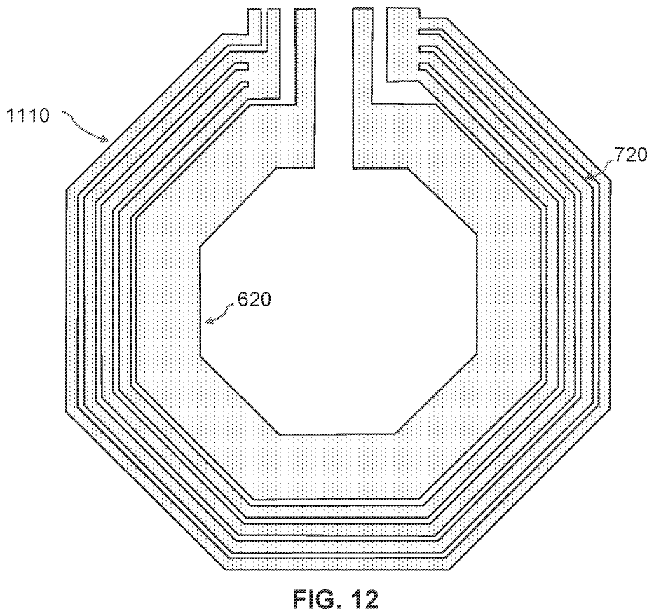

FIG. 12 shows a top view of an exemplary layout of the fifth inductor 1110 according to certain aspects. In this example, the fifth inductor 1110 includes a loop inductor coupled at one end to the third inductor 720, and formed in the same metal layer (e.g., first metal layer) as the third inductor 720 and the first inductor 620. However, it is to be appreciated that the fifth inductor 1110 is not limited to this example.

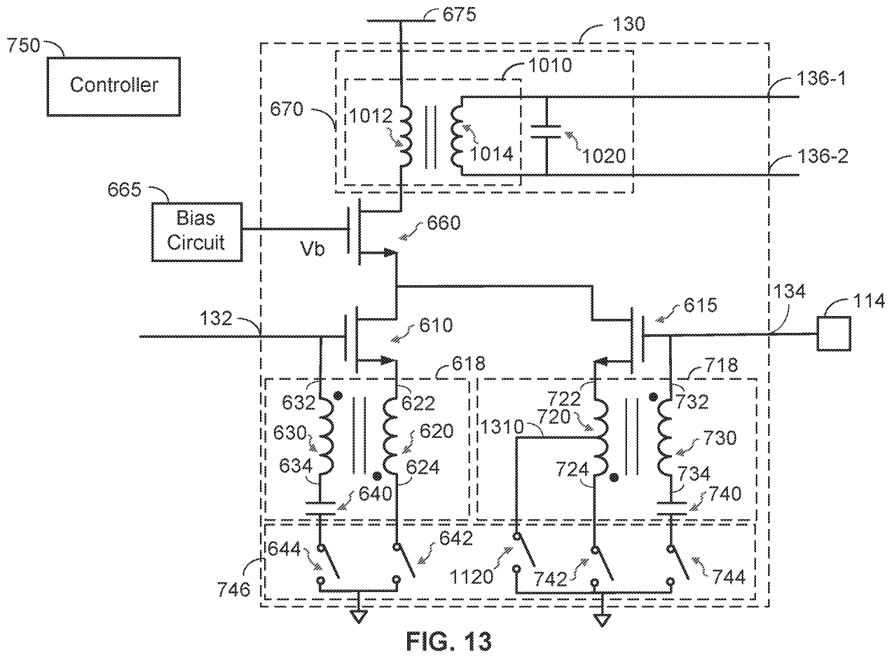

FIG. 13 shows another example for implementing programmable source degeneration inductance in the LNA 130 according to certain aspects. In this example, the fifth switch 1120 is coupled between a tap 1310 on the third inductor 720 and ground (or some reference potential). The tap 1310 is located between the first terminal 722 and the second terminal 724 of the third inductor 720.

In this example, the controller 750 may program the source degeneration inductance of the second transistor 615 by controlling the fifth switch 1120 and the third switch 742. For example, the controller 750 may program the source degeneration inductance to a first inductance value by closing the third switch 742 and opening the fifth switch 1120. In this case, the first inductance value is approximately equal to the inductance of the third inductor 720. The controller 750 may program the source degeneration inductance to a second inductance value by closing both the third switch 742 and the fifth switch 1120. In this case, the second inductance value is approximately equal to the inductance of the portion of the third inductor 720 located between the first terminal 722 of the third inductor 720 and the tap 1310, which lowers the source degeneration inductance (i.e., the second inductance value is lower than the first inductance value). This is because the portion of the third inductor 720 located between the tap 1310 and the second terminal 724 is shorted by the fifth switch 1120.

As discussed above, the controller 750 may program the source degeneration inductance to the first inductance value for higher linearity, and program the source degeneration inductance to the second inductance value for higher noise performance and higher gain. For example, the controller 750 may program the source degeneration inductance to the first inductance value for higher linearity when the signal strength of the receive RF signal is high to reduce distortion caused by the LNA 130. The controller 750 may program the source degeneration inductance to the second inductance value for higher noise performance and higher gain when the signal strength of the receive RF signal is low to increase sensitivity.

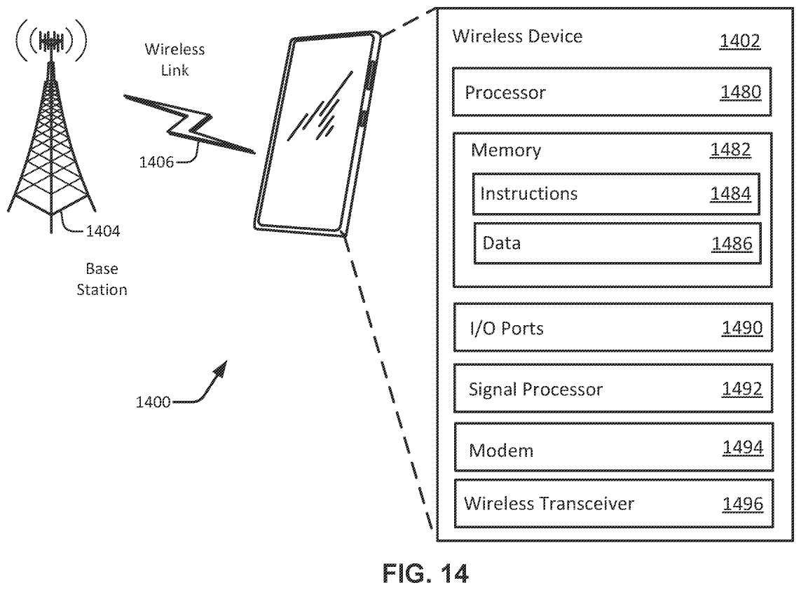

FIG. 14 is a diagram of an environment 1400 that includes a wireless device 1402 and a base station 1404. In the environment 1400, the wireless device 1402 communicates with the base station 1404 via a wireless link 1406. As shown, the wireless device 1402 is depicted as a smart phone. However, it is to be understood that the wireless device 1402 may be implemented as any suitable wireless device, such as a cellular base station, a broadband router, an access point, a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

The base station 1404 communicates with the wireless device 1402 via the wireless link 1406, which may be implemented as any suitable type of wireless link. Although depicted as a base station tower of a cellular radio network, the base station 1404 may represent or be implemented as another device, such as a satellite, a terrestrial broadcast tower, an access point, a peer-to-peer device, a mesh network node, and so forth. The wireless link 1406 may include a downlink of data and/or control information communicated from the base station 1404 to the wireless device 1402 and an uplink of other data and/or control information communicated from the wireless device 1402 to the base station 1404. The wireless link 1406 may be implemented using any suitable communication protocol or standard, such as 3rd Generation Partnership Project Long-Term Evolution (3GPP LTE, 3GPP NR 5G), IEEE 1402.1414, IEEE 1402.1414, Bluetooth™, and so forth.

The wireless device 1402 includes a processor 1480 and a memory 1482. The memory 1482 may be or form a portion of a computer readable storage medium. The processor 1480 may include any type of processor, such as an application processor or a multi-core processor, that is configured to execute processor-executable instructions stored in the memory 1482. The memory 1482 may include any suitable type of data storage media, such as a volatile memory (e.g., random access memory (RAM)), a non-volatile memory (e.g., Flash memory), an optical media, a magnetic media (e.g., disk or tape), or any combination thereof. In the context of this disclosure, the memory 1482 may store instructions 1484, data 1486, and other information of the wireless device 1402.

The wireless device 1402 may also include input/output (I/O) ports 1490. The I/O ports 1490 enable data exchanges or interaction with other devices, networks, or users or between components of the wireless device 1402.

The wireless device 1402 may further include a signal processor (SP) 1492 (e.g., such as a digital signal processor (DSP)). The signal processor 1492 may function similar to the processor 1480 and may be capable of executing instructions and/or processing information in conjunction with the memory 1482.

For communication purposes, the wireless device 1402 also includes a modem 1494 (e.g., baseband processor), a wireless transceiver 1496, and one or more antennas (e.g., the antenna 310). The wireless transceiver 1496 may include the PA 120, the transformer 140, the switch 160, the LNA 130, the external switch 410, and/or the external LNA 420 discussed above. The wireless transceiver 1496 provides connectivity to respective networks (e.g., the base station 1404) and other wireless devices connected therewith using RF signals. The wireless transceiver 1496 may facilitate communication over any suitable type of wireless network, such as a wireless local area network (LAN) (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

Implementation examples are described in the following numbered clauses:

1. A system comprising:
a low-noise amplifier (LNA) comprising:
   a first transistor, wherein a gate of the first transistor is coupled to a first input of the LNA;
a second transistor, wherein a gate of the second transistor is coupled to a second input of the LNA;
   a load coupled to a drain of the first transistor and a drain of the second transistor;
   a first reactive impedance matching network comprising a first inductor and a second inductor inductively coupled with the first inductor, wherein the first inductor is coupled to a source of the first transistor, and the second inductor is coupled to the gate of the first transistor;
   a second reactive impedance matching network comprising a third inductor and a fourth inductor inductively coupled with the third inductor, wherein the third inductor is coupled to a source of the second transistor, and the fourth inductor is coupled to the gate of the second transistor; and
   a switching circuit configured to enable or disable each of the first reactive impedance matching network and the second reactive impedance matching network.

2. The system of clause 1, wherein the switching circuit comprises:
a first switch coupled between the first inductor and a ground;
a second switch coupled between the second inductor and the ground;
a third switch coupled between the third inductor and the ground; and
a fourth switch coupled between the fourth inductor and the ground.

3. The system of clause 1, wherein the switching circuit comprises:
a first switch coupled between the first inductor and a ground and coupled between the second inductor and the ground; and
a second switch coupled between the third inductor and the ground and coupled between the fourth inductor and the ground.

4. The system of any one of clauses 1 to 3, further comprising:
a first pad;
a second pad coupled to the second input of the LNA;
a power amplifier (PA); and
a transformer including a fifth inductor and a sixth inductor inductively coupled with the fifth inductor, wherein the fifth inductor is coupled between a first output of the PA and a second output of the PA, and the sixth inductor is coupled between the first pad and the first input of the LNA.

5. The system of clause 4, further comprising a switch coupled between the sixth inductor and a ground.

6. The system of clause 4 or 5, further comprising:
an antenna; and
a switch coupled to the antenna, the first pad, and the second pad, wherein the switch is configured to couple the antenna to the first pad or the second pad.

7. The system of clause 6, further comprising a controller configured to cause the switching circuit to disable the first reactive impedance matching network and enable the second reactive impedance matching network.

8. The system of clause 4 or 5, further comprising:
an antenna;
a second LNA, wherein an output of the second LNA is coupled to the second pad; and
a switch coupled to the antenna, the first pad, and an input of the second LNA, wherein the switch is configured to couple the antenna to the first pad or the input of the second LNA.

9. The system of clause 8, further comprising a controller configured to cause the switching circuit to disable the first reactive impedance matching network and enable the second reactive impedance matching network.

10. The system of any one of clauses 1 to 9, wherein the LNA further comprises a third transistor, a source of the third transistor is coupled to the drain of the first transistor and the drain of the second transistor, a gate of the third transistor is coupled to a bias circuit, and the load is coupled between a supply rail and a drain of the third transistor.

11. The system of clause 10, wherein the load comprises a transformer including a fifth inductor and a sixth inductor inductively coupled with the fifth inductor, wherein the fifth inductor is coupled between the supply rail and the drain of the third transistor, and the sixth inductor is coupled between a first output of the LNA and a second output of the LNA.

12. The system of any one of clauses 1 to 11, wherein:
the second inductor comprises a first spiral inductor;
the fourth inductor comprises a second spiral inductor; and
the first spiral inductor is located within an area enclosed by the second spiral inductor.

13. The system of any one of clauses 1 to 11, wherein:
the first inductor comprises a first loop inductor;
the third inductor comprises a second loop inductor; and
the first loop inductor is located within the second loop inductor.

14. The system of clause 13, wherein the third inductor further comprises a third loop inductor coupled in parallel with the second loop inductor.

15. The system of any one of clauses 1 to 11, wherein:
the second inductor comprises a first spiral inductor; and
the fourth inductor comprises a second spiral inductor interleaved with the first spiral inductor.

16. The system of any one of clauses 1 to 15, wherein the system is integrated on a chip.

17. A system comprising:
a low-noise amplifier (LNA) comprising:
a first transistor, wherein a gate of the first transistor is coupled to a first input of the LNA;
a first inductor;
a first switch, wherein the first inductor and the first switch are coupled in series between a source of the first transistor and a ground;
a second inductor inductively coupled with the first inductor;
a second switch, wherein the second inductor and the second switch are coupled in series between the gate of the first transistor and the ground;
a second transistor, wherein a gate of the second transistor is coupled to a second input of the LNA;
a third inductor;
a third switch, wherein the third inductor and the third switch are coupled in series between a source of the second transistor and the ground;
a fourth inductor inductively coupled with the third inductor;
a fourth switch, wherein the fourth inductor and the fourth switch are coupled in series between the gate of the second transistor and the ground; and
a load coupled to a drain of the first transistor and a drain of the second transistor.

18. The system of clause 17, wherein the LNA further comprises:
a fifth inductor; and
a fifth switch, wherein the fifth inductor and the fifth switch are coupled in series between the source of the second transistor and the ground.

19. The system of clause 17, wherein the LNA further comprises a shunt switch coupled between a tap on the third inductor and the ground.

20. The system of any one of clauses 17 to 19, wherein:
the second inductor comprises a first spiral inductor;
the fourth inductor comprises a second spiral inductor; and
the first spiral inductor is located within an area enclosed by the second spiral inductor.

21. The system of any one of clauses 17 to 19, wherein:
the first inductor comprises a first loop inductor;
the third inductor comprises a second loop inductor; and
the first loop inductor is located within the second loop inductor.

22. The system of clause 21, wherein the third inductor further comprises a third loop inductor coupled in parallel with the second loop inductor.

23. The system of any of clauses 17 to 19, wherein:
the second inductor comprises a first spiral inductor; and
the fourth inductor comprises a second spiral inductor interleaved with the first spiral inductor.

24. The system of any one of clauses 17 to 23, further comprising:
a first pad;
a second pad coupled to the second input of the LNA;
a power amplifier (PA); and
a transformer including a fifth inductor and a sixth inductor inductively coupled with the fifth inductor, wherein the fifth inductor is coupled between a first output of the PA and a second output of the PA, and the sixth inductor is coupled between the first pad and the first input of the LNA.

25. The system of clause 24, further comprising a fifth switch coupled between the sixth inductor and the ground.

26. The system of clause 24 or 25, further comprising:
an antenna; and
a switch coupled to the antenna, the first pad, and the second pad, wherein the switch is configured to couple the antenna to the first pad or the second pad.

27. The system of clause 26, further comprising a controller configured to open the first switch and the second switch and close the third switch and the fourth switch.

28. The system of clause 24 or 25, further comprising:
an antenna;
a second LNA, wherein an output of the second LNA is coupled to the second pad; and
a switch coupled to the antenna, the first pad, and an input of the second LNA, wherein the switch is configured to couple the antenna to the first pad or the input of the second LNA.

29. The system of clause 28, further comprising a controller configured to open the first switch and the second switch and close the third switch and the fourth switch.

30. The system of any one of clauses 17 to 29, wherein the LNA further comprises a third transistor, a source of the third transistor is coupled to the drain of the first transistor and the drain of the second transistor, a gate of the third transistor is coupled to a bias circuit, and the load is coupled between a supply rail and a drain of the third transistor.

31. The system of clause 30, wherein the load comprises a transformer including a fifth inductor and a sixth inductor inductively coupled with the fifth inductor, wherein the fifth inductor is coupled between the supply rail and the drain of the third transistor, and the sixth inductor is coupled between a first output of the LNA and a second output of the LNA.

32. The system of any one of clauses 17 to 31, wherein the system is integrated on a chip.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. It is also to be appreciated that an “inductor” may include multiple inductors coupled in series. It is also to be appreciated than an “input” may be a single-ended input, a differential input, or one of two inputs of a differential input, and an “output” may be a single-ended output, a differential output, or one of two outputs of a differential output.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. Further, it is to be appreciated that elements are not limited to the numerical designations used above to describe aspects of the present disclosure.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system comprising:
a low-noise amplifier (LNA) comprising:
a first transistor, wherein a gate of the first transistor is coupled to a first input of the LNA;
a second transistor, wherein a gate of the second transistor is coupled to a second input of the LNA;
a load coupled to a drain of the first transistor and a drain of the second transistor;
a first reactive impedance matching network comprising a first inductor and a second inductor inductively coupled with the first inductor, wherein the first inductor is coupled to a source of the first transistor, and the second inductor is coupled to the gate of the first transistor;
a second reactive impedance matching network comprising a third inductor and a fourth inductor inductively coupled with the third inductor, wherein the third inductor is coupled to a source of the second transistor, and the fourth inductor is coupled to the gate of the second transistor; and
a switching circuit configured to enable or disable each of the first reactive impedance matching network and the second reactive impedance matching network.

2. The system of claim 1, wherein the switching circuit comprises:
a first switch coupled between the first inductor and a ground;
a second switch coupled between the second inductor and the ground;
a third switch coupled between the third inductor and the ground; and
a fourth switch coupled between the fourth inductor and the ground.

3. The system of claim 1, wherein the switching circuit comprises:
a first switch coupled between the first inductor and a ground and coupled between the second inductor and the ground; and
a second switch coupled between the third inductor and the ground and coupled between the fourth inductor and the ground.

4. The system of claim 1, further comprising:
a first pad;
a second pad coupled to the second input of the LNA;
a power amplifier (PA); and
a transformer including a fifth inductor and a sixth inductor inductively coupled with the fifth inductor, wherein the fifth inductor is coupled between a first output of the PA and a second output of the PA, and the sixth inductor is coupled between the first pad and the first input of the LNA.

5. The system of claim 4, further comprising a switch coupled between the sixth inductor and a ground.

6. The system of claim 4, further comprising:
an antenna; and
a switch coupled to the antenna, the first pad, and the second pad, wherein the switch is configured to couple the antenna to the first pad or the second pad.

7. The system of claim 6, further comprising a controller configured to cause the switching circuit to disable the first reactive impedance matching network and enable the second reactive impedance matching network.

8. The system of claim 4, further comprising:
an antenna;
a second LNA, wherein an output of the second LNA is coupled to the second pad; and
a switch coupled to the antenna, the first pad, and an input of the second LNA, wherein the switch is configured to couple the antenna to the first pad or the input of the second LNA.

9. The system of claim 8, further comprising a controller configured to cause the switching circuit to disable the first reactive impedance matching network and enable the second reactive impedance matching network.

10. The system of claim 1, wherein the LNA further comprises a third transistor, a source of the third transistor is coupled to the drain of the first transistor and the drain of the second transistor, a gate of the third transistor is coupled to a bias circuit, and the load is coupled between a supply rail and a drain of the third transistor.

11. The system of claim 10, wherein the load comprises a transformer including a fifth inductor and a sixth inductor inductively coupled with the fifth inductor, wherein the fifth inductor is coupled between the supply rail and the drain of the third transistor, and the sixth inductor is coupled between a first output of the LNA and a second output of the LNA.

12. The system of claim 1, wherein:
the second inductor comprises a first spiral inductor;
the fourth inductor comprises a second spiral inductor; and
the first spiral inductor is located within an area enclosed by the second spiral inductor.

13. The system of claim 1, wherein:
the first inductor comprises a first loop inductor;
the third inductor comprises a second loop inductor; and
the first loop inductor is located within the second loop inductor.

14. The system of claim 13, wherein the third inductor further comprises a third loop inductor coupled in parallel with the second loop inductor.

15. The system of claim 1, wherein:
the second inductor comprises a first spiral inductor; and
the fourth inductor comprises a second spiral inductor interleaved with the first spiral inductor.

16. The system of claim 1, wherein the system is integrated on a chip.

17. A system comprising:
a low-noise amplifier (LNA) comprising:
a first transistor, wherein a gate of the first transistor is coupled to a first input of the LNA;
a first inductor;
a first switch, wherein the first inductor and the first switch are coupled in series between a source of the first transistor and a ground;
a second inductor inductively coupled with the first inductor;
a second switch, wherein the second inductor and the second switch are coupled in series between the gate of the first transistor and the ground;
a second transistor, wherein a gate of the second transistor is coupled to a second input of the LNA;
a third inductor;
a third switch, wherein the third inductor and the third switch are coupled in series between a source of the second transistor and the ground;
a fourth inductor inductively coupled with the third inductor;
a fourth switch, wherein the fourth inductor and the fourth switch are coupled in series between the gate of the second transistor and the ground; and
a load coupled to a drain of the first transistor and a drain of the second transistor.

18. The system of claim 17, wherein the LNA further comprises:
a fifth inductor; and
a fifth switch, wherein the fifth inductor and the fifth switch are coupled in series between the source of the second transistor and the ground.

19. The system of claim 17, wherein the LNA further comprises a shunt switch coupled between a tap on the third inductor and the ground.

20. The system of claim 17, further comprising:
a first pad;
a second pad coupled to the second input of the LNA;
a power amplifier (PA); and
a transformer including a fifth inductor and a sixth inductor inductively coupled with the fifth inductor, wherein the fifth inductor is coupled between a first output of the PA and a second output of the PA, and the sixth inductor is coupled between the first pad and the first input of the LNA.
